(19) United States
(12) Patent Application Publication
(10) Pub. No.: US 2020/0262741 A1
(43) Pub. Date: Aug. 20, 2020

(54) CONDUCTIVE PASTE FOR SOLAR CELL ELECTRODE, AND SOLAR CELL MANUFACTURED USING SAME

(71) Applicant: LS-NIKKO COPPER INC., Ulsan (KR)

(72) Inventors: Mun Seok JANG, Seoul (KR); Hwa Young NOH, Hwaseong (KR); In Chul KIM, Yongin (KR); Min Soo KO, Seoul (KR); Tae Hyun JUN, Seongnam (KR); Hwa Joong KIM, Seoul (KR); Kang Ju PARK, Seongnam (KR); Chung Ho KIM, Namyangju (KR)

(21) Appl. No.: 16/761,729

(22) PCT Filed: Oct. 18, 2018
(86) PCT No.: PCT/KR2018/012332

§ 371 Date: May 5, 2020

(30) Foreign Application Priority Data
Nov. 6, 2017 (KR) 10-2017-0146994

(51) Int. Cl. C03C 8/22; H01L 31/0224; C03C 8/18; C03C 8/10; C03C 4/14

(52) U.S. Cl. CPC C03C 8/22; H01L 31/022425; C03C 8/18; C03C 2205/00; C03C 4/14; C03C 2204/00; C03C 8/10

(57) ABSTRACT

The present invention relates to a conductive paste for a solar cell electrode, comprising: a metal powder; glass frit; and organic vehicles, wherein the glass frit includes a first glass frit having a first glass transition temperature and a second glass frit having a second glass transition temperature that is higher than the first glass transition temperature, wherein the glass frit is contained in an amount of 1-10% by weight with respect to the total weight of the paste, the content of the first glass frit being larger than that of the second glass frit. The present invention can improve the conversion efficiency and adhesion characteristics of a solar cell by using two or more kinds of glass frits having different glass transition temperatures in combination.

### TECHNICAL FIELD

The present invention relates to a conductive paste used for forming an electrode of a solar cell, and a solar cell manufactured using the same.

### BACKGROUND ART

A solar cell is a semiconductor device that converts solar energy into electrical energy, and generally has a p-n junction type. The basic structure of the solar cell is the same as that of a diode. FIG. 1 illustrates a structure of a general solar cell device. The solar cell device is generally constructed using a p-type silicon semiconductor substrate 10 having a thickness of 180 to 250 μm. An n-type impurity layer 20 having a thickness of 0.3 to 0.6 μm is formed on a light-receiving surface side of the silicon semiconductor substrate, and an anti-reflection film 30 and a front electrode 100 are formed thereon. Further, a back aluminum electrode 50 is formed on a back surface of the p-type silicon semiconductor substrate.

The front electrode 100 is formed in such a manner that a conductive paste formed by mixing silver-based conductive particles (silver powder), a glass frit, an organic vehicle, and additives is applied on the anti-reflection film 30, followed by firing. The back aluminum electrode 50 is formed in such a manner that an aluminum paste composition composed of an aluminum powder, a glass frit, an organic vehicle, and additives is applied by screen printing or the like, followed by drying, and then firing at a temperature of equal to or greater than 660° C. (melting point of aluminum). During firing, aluminum diffuses into the p-type silicon semiconductor substrate, thereby forming an Al—Si alloy layer between the back electrode and the p-type silicon semiconductor substrate, and at the same time, a p+layer 40 is formed as an impurity layer by diffusion of aluminum atoms. The presence of such a p+layer prevents recombination of electrons and obtains a back surface field (BSF) effect that improves collection efficiency of generated carriers. A back silver electrode 60 may be further positioned under the back aluminum electrode 50.

Because a unit solar cell including a solar cell electrode as above has a low electromotive force, a photovoltaic module formed by connecting a plurality of unit solar cell cells to have an appropriate electromotive force is used. Here, respective unit solar cells are connected to each other by conductor ribbons of a predetermined length coated with lead. In the related art, to increase adhesion between a solar cell electrode and a ribbon, the component or amount of glass frit is adjusted or an inorganic element is added. In this case, however, there arises a problem in that the glass transition temperature of the glass frit may decrease, leading to a deterioration in electrical characteristics of the solar cell electrode.

### DISCLOSURE

### Technical Problem

An objective of the present invention is to provide a conductive paste for a solar cell electrode, wherein a glass frit in the composition of the conductive paste is used by mixing at least two types of glass frits having different glass transition temperatures, whereby the glass frit in the electrode is evenly distributed, making it possible to improve conversion efficiency and adhesion characteristics of the solar cell.

However, the objectives of the present invention are not limited to the above-mentioned objective, and other objectives not mentioned will be clearly understood by those skilled in the art from the following description.

### Technical Solution

The present invention provides a conductive paste for a solar cell electrode, the conductive paste including: a metal powder; a glass frit; and an organic vehicle, wherein the glass frit may include a first glass frit having a first glass transition temperature and a second glass frit having a second glass transition temperature higher than the first glass transition temperature, the glass frit may be included in an amount of 1 to 10% by weight with respect to a total weight of the conductive paste, and an amount of the first glass frit may be greater than an amount of the second glass frit.

Further, a weight ratio of the first glass frit to the second glass frit may be 1:0.5 to 0.7.

Further, each of the first glass transition temperature and the second glass transition temperature may be 200 to 500° C., and the second glass transition temperature may be higher than the first glass transition temperature by equal to or greater than 10° C.

Further, with respect to the total weight of the conductive paste, the metal powder may be included in an amount of 80 to 90% by weight, and the organic vehicle may be included in an amount of 5 to 15% by weight.

Further, each of the first and second glass frits may include at least two of PbO, TeO₂, Bi₂O₃, SiO₂, B₂O₃, Al₂O₃, ZnO, WO₃, Sb₂O₃, an oxide of an alkali metal, and an oxide of an alkaline earth metal.

Further, each of the first glass frit and the second glass frit may include at least one selected from the group consisting of Pb—Te—Si—B-based, Pb—Te—Bi-based, Pb—Te—Si—Sb3-based, Pb—Te—Si—Bi—Zn—W-based, Si—Te—Bi—Zn—W-based, and Si—Te—Bi2-Zn—W-based glass frits.

The conductive paste may further include a metal oxide, wherein the metal oxide may include at least one selected from NiO, CuO, MgO, CaO, RuO, and MoO.

Further, the metal oxide may be included in an amount of 0.1 to 1% by weight with respect to the total weight of the conductive paste.

The present invention further provides a solar cell, including: a front electrode on a substrate; and a back electrode under the substrate, wherein the front electrode may be produced by applying the conductive paste, followed by drying and firing.

### Advantageous Effects

A conductive paste according to the present invention is used by mixing at least two types of glass frits having different glass transition temperatures, but a glass frit having a low glass transition temperature has a high amount in a predetermined range, thereby making it possible to uniformly distribute the glass frits in an electrode during electrode formation. As a result, it is possible to ensure an excellent etching ability during firing, prevent a shunt problem due to excessive etching, and prevent interference with a reaction with an anti-reflection film, thereby lowering contact resistance to increase conversion efficiency of a solar cell. Additionally, even when an excessive amount of glass frit is included, soldering characteristics are enhanced to improve adhesion characteristics.

### DESCRIPTION OF DRAWINGS

FIG. 1 is a schematic sectional view illustrating a general solar cell device.

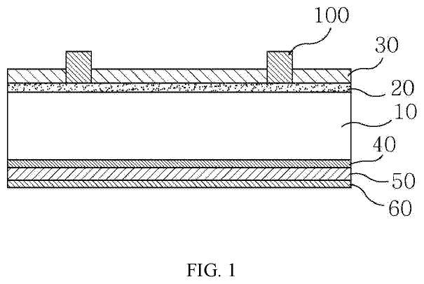

### MODE FOR INVENTION

Prior to describing the present invention in detail below, it should be understood that the terms used herein are merely intended to describe specific embodiments and are not to be construed as limiting the scope of the present invention, which is defined by the appended claims. Unless otherwise defined, all terms including technical and scientific terms used herein have the same meaning as commonly understood by one of ordinary skill in the art to which this invention belongs.

Throughout this specification and the claims, unless otherwise defined, the terms “comprise”, “comprises”, and “comprising” will be understood to imply the inclusion of a stated object, a step or groups of objects, and steps, but not the exclusion of any other objects, steps or groups of objects or steps.

Meanwhile, unless otherwise noted, various embodiments of the present invention may be combined with any other embodiments. In particular, any feature which is mentioned preferably or favorably may be combined with any other features which may be mentioned preferably or favorably. Hereinafter, a description will be given of embodiments of the present invention and effects thereof with reference to the accompanying drawings.

A paste according to an embodiment of the present invention is a paste suitable for use in forming a solar cell electrode, and a conductive paste including at least two types of glass frits having different glass transition temperatures is provided. More in detail, the conductive paste according to the present invention includes a metal powder, a glass frit, an organic vehicle, and other additives.

As the metal powder, a silver powder, copper powder, nickel powder, aluminum powder, or the like may be used. The silver powder is mainly used for a front electrode, and the aluminum powder is mainly used for a back electrode. As the metal powder, one of the above-described powders may be used alone, an alloy of the above-described metals may be used, or at least two of the above-described powders may be used as a mixed powder.

The amount of the metal powder is preferably 40 to 95% by weight with respect to the total weight of a conductive paste composition, considering electrode thickness formed during printing and linear resistance of the electrode. When the amount of the metal powder is less than 40% by weight, resistivity of a formed electrode may be high, and when the amount of the metal powder is greater than 95% by weight, the amount of other components may be insufficient, and thus there is a problem that the metal powder may not be uniformly dispersed. More preferably, the amount of the metal power is 80 to 90% by weight.

When the conductive paste includes a silver powder to form the front electrode of the solar cell, the silver powder is preferably a pure silver powder, and in addition, a silver-coated composite powder in which a silver layer is formed on at least the surface thereof, or an alloy including silver as a main component may be used. Further, other metal powders may be mixed and used. Examples may include aluminum, gold, palladium, copper, and nickel.

The metal powder may have an average particle diameter D50 of 0.1 to 10 μm, and preferably 0.5 to 5 μm when considering ease of pasting and density during firing, and the shape thereof may be at least one of spherical, needle-like, plate-like, and amorphous. The metal powder may be used by mixing two or more powders having different average particle diameters, particle size distributions, and shapes.

The glass frit may be used by mixing at least two types of glass frits having different glass transition temperatures. For example, the glass frit may include a first glass frit having a first glass transition temperature Tg₁, and a second glass frit having a second glass transition temperature of Tg₂. Each of the first glass transition temperature Tg₁ and the second glass transition temperature Tg₂ may be 200 to 500° C., and the second glass transition temperature Tg₂ may be higher than the first glass transition temperature Tg₁ by equal to or greater than 10° C. Preferably, the difference between the first glass transition temperature Tg₁ and the second glass transition temperature Tg₂ is equal to or greater than 50° C.

Each of the first glass frit and the second glass frit may include at least two of PbO, TeO₂, Bi₂O₃, SiO₂, B₂O₃, Al₂O₃, ZnO, WO₃, Sb₂O₃, an oxide of an alkali metal (Li, Na, K, and the like), and an oxide of an alkaline earth metal (Ca, Mg, and the like). For example, each of the first glass frit and the second glass frit may include at least one selected from the group consisting of Pb—Te—Si—B-based, Pb—Te—Bi-based, Pb—Te—Si—Sb3-based, Pb—Te—Si—Bi—Zn—W-based, Si—Te—Bi—Zn—W-based, and Si—Te—Bi2-Zn—W-based glass frits, but is not limited thereto.

The first glass transition temperature Tg₁ and the second glass transition temperature Tg₂ may be adjusted by changing the components and/or amounts of the first glass frit and the second glass frit, respectively. In an example, each of the first and second glass frits may include PbO—TeO₂—SiO₂—B₂O₃, but the amount of TeO₂ in the first glass frit (e.g., % by weight with respect to the total weight of the first glass frit) may be greater than the amount of TeO₂ in the second glass frit (e.g., % by weight with respect to the total weight of the second glass frit). That is, when the amount of TeO₂ in the glass frit is high, the glass transition temperature Tg may be relatively low. As another example, each of the first and second glass frits may include at least two of PbO, TeO₂, Bi₂O₃, SiO₂, B₂O₃, Al₂O₃, ZnO, WO₃, and Sb₂O₃, and the first glass frit may have a lower glass transition temperature than the second glass frit by further including an alkali metal oxide (e.g., LiO₂) or an alkaline earth metal oxide (e.g., CaO).

The average particle diameter of the glass frit is not limited, but may fall within the range of 0.5 to 10 μm, and the glass frit may be used by mixing different types of particles having different average particle diameters. Preferably, at least one type of glass frit has an average particle diameter D50 of equal to or greater than 2 μm and equal to or less than 10 μm.

The amount of the glass frit is preferably 1 to 10% by weight with respect to the total weight of the conductive paste composition. When the amount of the glass frit is less than 1% by weight, there is a possibility that electrical resistivity may increase due to incomplete firing. When the amount of the glass frit is greater than 10% by weight, there is a possibility that electrical resistivity may increase due to too many glass components in a fired body of the glass powder.

In the glass frit in the above amount range, it may be preferable that the amount (e.g., % by weight) of the first glass frit is higher than the amount (e.g., % by weight) of the second glass frit. That is, when at least two types of glass frits having different glass transition temperatures are mixed, it may be preferable that the amount of glass frit having a low glass transition temperature is relatively large. For example, the weight ratio of the first glass frit to the second glass frit may be 1:0.5 to 0.7. When an electrode is formed within this amount range, glass frits may be uniformly distributed in the electrode. As a result, an excellent etching ability is ensured during firing, a shunt problem due to excessive etching is prevented, and a reaction with an anti-reflection film does not interfered, thereby lowering contact resistance to increase conversion efficiency of the solar cell. Additionally, even when an excessive amount of glass frit is included, soldering characteristics are enhanced to improve adhesion characteristics.

The organic vehicle is not limited, but may include an organic binder, a solvent, and the like. The use of the solvent may be omitted in some cases. The organic vehicle is not limited, but is preferably included in an amount of 5 to 15% by weight with respect to the total weight of the conductive paste composition.

The organic vehicle is required to have characteristics such as maintaining a uniform mixture of the metal powder, the glass frit, and the like. For example, when the conductive paste is applied to a substrate by screen printing, there is a need for characteristics that make the conductive paste homogeneous to suppress blurring and flow of a printed pattern, and also improve dischargeability and plate separation characteristics of the conductive paste from a screen plate.

The organic binder included in the organic vehicle is not limited, but examples thereof may include a cellulose ester compound such as cellulose acetate, cellulose acetate butyrate, and the like; a cellulose ether compound such as ethyl cellulose, methyl cellulose, hydroxy propyl cellulose, hydroxy ethyl cellulose, hydroxy propyl methyl cellulose, hydroxy ethyl methyl cellulose, and the like; an acrylic compound such as polyacrylamide, polymethacrylate, polymethyl methacrylate, polyethyl methacrylate, and the like; and a vinyl compound such as polyvinyl butyral, polyvinyl acetate, polyvinyl alcohol, and the like. At least one of the organic binders may be selected and used.

As a solvent used for dilution of the composition, it is preferable to use at least one selected from compounds consisting of alpha-terpineol, texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol mono butyl ether, diethylene glycol mono butyl ether acetate, and the like.

The conductive paste composition according to the present invention may further include, as needed, an additive generally known, for example, a dispersant, plasticizer, a viscosity modifier, a surfactant, an oxidizing agent, a metal organic compound, and the like.

The above-described conductive paste for the solar cell electrode may be prepared by mixing and dispersing the metal powder, glass frit mixed as described above, organic binder, solvent, and additives, followed by filtering and degassing.

As another embodiment of the present invention, a glass frit may include three types of glass frits having different glass transition temperatures. For example, the glass frit may include the first glass frit and the second glass frit described above, and a third glass frit having a glass transition temperature Tg₃. Here, the second glass transition temperature Tg₂ may be higher than the first glass transition temperature Tg₁ and lower than the third glass transition temperature Tg₃. Preferably, the difference between the first glass transition temperature Tg₁ and the second glass transition temperature Tg₂ is equal to or greater than 50° C. Similarly, the difference between the second glass transition temperature Tg₂ and the third glass transition temperatures Tg₃ may be equal to or greater than 50° C. Further, in the glass frit, the amount of the second glass frit may be lower than the first glass frit, and may be higher than the third glass frit.

As another embodiment of the present invention, the conductive paste described above may further include a metal oxide. That is, the conductive paste according to another embodiment of the present invention may include a metal powder, a glass frit, an organic vehicle, a metal oxide, and other additives. The metal oxide is not limited, but may include at least one selected from NiO, CuO, MgO, CaO, RuO, MoO, and Bi₂O₃. The average particle diameter of the metal oxide may be 0.01 to 5 μm, and considering an effect thereof, preferably 0.02 to 2 μm. The metal oxide may be included in an amount of 0.1 to 1% by weight with respect to the total weight of the conductive paste, and may provide improved adhesion characteristics within this amount range.

The present invention also provides a method of forming an electrode of a solar cell, characterized in that the conductive paste is coated on a substrate, dried, and fired, and provides a solar cell electrode produced by the method. In the method of forming the solar cell electrode according to the present invention, except that a conductive paste including a coated glass frit is used, the substrate, printing, drying, and firing can be implemented by using methods generally used in manufacturing of solar cells. For example, the substrate may be a silicon wafer.

Further, the conductive paste according to the present invention is applicable to a structure such as crystalline solar cell (P-type, N-type), passivated emitter solar cell (PESC), passivated emitter and rear cell (PERC), and passivated emitter rear locally diffused (PERL) structures, and also to modified printing processes such as double printing, dual printing, and the like.

### EXAMPLES AND COMPARATIVE EXAMPLES

With the composition as shown in Table 1 below (e.g., % by weight), a mixed glass frit, a metal oxide, an organic binder, a solvent, and dispersant were added and dispersed using a mixer, and then a silver powder (spherical shape, average particle diameter of 1 μm) was mixed and dispersed using a 3-roll mill. Thereafter, degassing under reduced pressure was performed to prepare a conductive paste. The types, components, amounts, and glass transition temperatures of glass frits used in Examples 1 to 6 and Comparative Examples 1 to 5 are shown in Table 2.

TABLE 1

| | | | | | | | Compar- | Compar- | Compar- | Compar- | Compar- |
|---|---|---|---|---|---|---|---|---|---|---|---|
| | | | | | | | ative | ative | ative | ative | ative |
| Classification | Example 1 | Example 2 | Example 3 | Example 4 | Example 5 | Example 6 | example 1 | example 2 | example 3 | example 4 | example 5 |
| Glass frit A | 3 | 3 | 1.5 | 3 | 3 | 3 | 2 | 3.5 | 5 | 4.5 | 4.5 |
| Glass frit B | 1.5 | 2 | 3 | — | — | 2 | 3 | 1.5 | — | 0.5 | — |
| Glass frit C | — | — | — | 1.5 | — | — | — | — | — | — | — |
| Glass frit D | — | — | — | — | 1.5 | — | — | — | — | — | — |
| Glass frit E | — | — | — | — | — | 1 | — | — | — | — | — |
| Metal oxide | 0.5 | — | 0.5 | 0.5 | 0.5 | — | — | — | — | — | 0.5 |
| (LiO₂) | | | | | | | | | | | |
| Organic binder | 1 | 1 | 1 | 1 | 1 | 1 | 1 | 1 | 1 | 1 | 1 |
| Solvent | 5 | 5 | 5 | 5 | 5 | 5 | 5 | 5 | 5 | 5 | 5 |
| Silver powder | 86 | 86 | 86 | 86 | 86 | 86 | 86 | 86 | 86 | 86 | 86 |
| Dispersant | 3 | 3 | 3 | 3 | 3 | 3 | 3 | 3 | 3 | 3 | 3 |

TABLE 2

| | | | | | Transition |
|---|---|---|---|---|---|
| | Component(% by weight) | | | | temperature |
| Classification | PbO | TeO₂ | SiO₂ | B₂O₃ | (Tg, ° C.) |
| Glass frit A | 67.5 | 15.5 | 10.4 | 6.6 | 230 |
| Glass frit B | 76.2 | 6.8 | 10.4 | 6.6 | 280 |
| Glass frit C | 69.0 | 14.0 | 10.4 | 6.6 | 240 |
| Glass frit D | 79.8 | 3.2 | 10.4 | 6.6 | 300 |
| Glass frit E | 82.5 | 0.5 | 10.4 | 6.6 | 350 |

Evaluation of Characteristics

A conductive paste prepared according to each of the above Examples 1 to 6 and Comparative Examples 1 to 5 was pattern-printed on a front surface of a wafer by screen printing using a 40 μm mesh, and dried at 200 to 350° C. for 20 to 30 seconds using a belt-type drying furnace. Thereafter, Al paste was printed on a back surface of the wafer and dried in the same manner. A cell formed in the above process was fired at 500 and 900° C. for 20 to 30 seconds using a belt-type firing furnace to produce a solar cell.

The produced cell was measured for conversion efficiency (Eff), short-circuit current (Isc), open-circuit voltage (Voc), fill factor (FF), and series resistance (Rs) and the results are shown in Table 3 below.

Further, after production of solar cells, adhesion characteristics were measured in such a manner that a SnPbAg-coated ribbon was bonded to an electrode, and then a tensile strength meter was used to pull a bonded portion in the 180-degree direction while holding one of the bonded portion to measure a force (N) required until a front electrode and the ribbon were delaminated. Measured adhesion values are shown in Table 3.

TABLE 3

| Classi- | Eff | Isc | Voc | FF | Rs | Adhesion |
|---|---|---|---|---|---|---|
| fication | (%) | (A) | (V) | (%) | (Ω) | (N) |
| Example 1 | 19.706 | 9.491 | 0.6386 | 77.74 | 0.00168 | 3.5 |
| Example 2 | 19.727 | 9.4918 | 0.6393 | 77.749 | 0.00177 | 3.2 |
| Example 3 | 19.688 | 9.4873 | 0.6382 | 77.735 | 0.00167 | 2.8 |
| Example 4 | 19.692 | 9.4892 | 0.6384 | 77.738 | 0.00169 | 3.0 |
| Example 5 | 19.730 | 9.4925 | 0.6394 | 77.751 | 0.00178 | 3.6 |
| Example 6 | 19.735 | 9.493 | 0.6397 | 77.754 | 0.00179 | 3.7 |
| Comparative | 19.631 | 9.482 | 0.6384 | 77.7 | 0.00198 | 3.0 |
| example 1 | | | | | | |
| Comparative | 19.549 | 9.487 | 0.6371 | 77.05 | 0.00211 | 2.7 |
| example 2 | | | | | | |
| Comparative | 19.689 | 9.479 | 0.6378 | 77.75 | 0.00173 | 2.1 |
| example 3 | | | | | | |
| Comparative | 19.624 | 9.4066 | 0.6379 | 78.21 | 0.00156 | 2.4 |
| example 4 | | | | | | |
| Comparative | 19.598 | 9.5216 | 0.6393 | 76.957 | 0.00207 | 2.3 |
| example 5 | | | | | | |

As shown in Table 3, it can be seen that when at least two types of glass frits having different glass transition temperatures were mixed and used, and the amount of a glass frit having a low glass transition temperature was high in a predetermined range (Examples 1, 2, 5, and 6), conversion efficiency and adhesion of solar cells were increased. In particular, referring to Example 6, it can be seen that when three types of glass frits having different glass transition temperatures were mixed and used, conversion efficiency and adhesion of solar cells were greatly increased. Further, when comparing Example 1 and Example 2, it can be seen that when a metal oxide was added in an amount of 0.1 to 1% by weight with respect to the total weight of the paste, adhesion was further increased. Furthermore, when comparing Examples 1, 4, and 5, it can be seen that when the difference in glass transition temperature between glass frits was 70° C. (Example 5), conversion efficiency and adhesion of solar cells were increased, compared to when the difference in glass transition temperature was 50° C. (Example 1) and when the difference in glass transition temperature was 10° C. (Example 4).

The features, structures, and effects illustrated in individual exemplary embodiments as above can be combined or modified with other exemplary embodiments by those skilled in the art. Therefore, content related to such combinations or modifications should be understood to fall within the scope of the present invention.

### DESCRIPTION OF THE REFERENCE NUMERALS IN THE DRAWINGS

10: p-type silicon semiconductor substrate
20: n-type impurity layer
30: anti-reflection film
40: p+layer (BSF: back surface field)
50: back aluminum electrode
60: back silver electrode
100: front electrode

1. A conductive paste for a solar cell electrode, the conductive paste comprising:
a metal powder;
a glass frit; and
an organic vehicle,
wherein the glass frit comprises a first glass frit having a first glass transition temperature and a second glass frit having a second glass transition temperature higher than the first glass transition temperature,
the glass frit is included in an amount of 1 to 10% by weight with respect to a total weight of the conductive paste, and
an amount of the first glass frit is greater than an amount of the second glass frit.

2. The conductive paste of claim 1, wherein a weight ratio of the first glass frit to the second glass frit is 1:0.5 to 0.7.

3. The conductive paste of claim 1, wherein each of the first glass transition temperature and the second glass transition temperature is 200 to 500° C., and
the second glass transition temperature is higher than the first glass transition temperature by equal to or greater than 10° C.

4. The conductive paste of claim 1, wherein with respect to the total weight of the conductive paste, the metal powder is included in an amount of 80 to 90% by weight, and the organic vehicle is included in an amount of 5 to 15% by weight.

5. The conductive paste of claim 1, wherein each of the first and second glass frits comprises at least two of PbO, TeO₂, Bi₂O₃, SiO₂, B₂O₃, Al₂O₃, ZnO, WO₃, Sb₂O₃, an oxide of an alkali metal, and an oxide of an alkaline earth metal.

6. The conductive paste of claim 5, wherein each of the first glass frit and the second glass frit comprises at least one selected from a group consisting of Pb—Te—Si—B-based, Pb—Te—Bi-based, Pb—Te—Si—Sb3-based, Pb—Te—Si—Bi—Zn—W-based, Si—Te—Bi—Zn—W-based, and Si—Te—Bi2-Zn—W-based glass frits.

7. The conductive paste of claim 1, further comprising:
a metal oxide, wherein the metal oxide comprises at least one selected from NiO, CuO, MgO, CaO, RuO, and MoO.

8. The conductive paste of claim 7, wherein the metal oxide is included in an amount of 0.1 to 1% by weight with respect to the total weight of the conductive paste.

9. A solar cell, comprising:
a front electrode on a substrate; and
a back electrode under the substrate,
wherein the front electrode is produced by applying the conductive paste of claim 1, followed by drying and firing.
